(19) United States
(12) Patent Application Publication
(10) Pub. No.: US 2014/0149056 A1
(43) Pub. Date: May 29, 2014

(54) MULTI-MODAL DATA IMPROVEMENT FOR POWER DISAGGREGATION SYSTEMS

(71) Applicants: Armand Michel Marie Lelkens, Heerlen (NL); Alessio Filippi, Eindhoven (NL); Paul Anthony Shrubsole, Arnhem (NL); Ying Wang, Eindhoven (NL); Paulus Henricus Antonius Dillen, Eindhoven (NL)

(72) Inventors: Armand Michel Marie Lelkens, Heerlen (NL); Alessio Filippi, Eindhoven (NL); Paul Anthony Shrubsole, Arnhem (NL); Ying Wang, Eindhoven (NL); Paulus Henricus Antonius Dillen, Eindhoven (NL)

(73) Assignee: KONINKLIJKE PHILIPS N.V., EINDHOVEN (NL)

(21) Appl. No.: 14/233,419

(22) PCT Filed: Jul. 12, 2012
(86) PCT No.: PCT/IB2012/053559

§ 371 Date: Jan. 17, 2014

Related U.S. Application Data
(60) Provisional application No. 61/509,224, filed on Jul. 19, 2011.

(51) Int. Cl. G01R 21/133

(52) U.S. Cl. CPC G01R 21/1333
USPC 702/61

(57) ABSTRACT

The present invention relates to a method and apparatus for disaggregation of energy consumption in a power distribution system. The basic idea is to look at the overall energy consumption and recognize the contributions of each single electrical device (120), e.g. for the purposes of providing a breakdown of energy consumption to users. Disaggregation is assisted by usage of multi-modal system data coming from various external data sources (106-1 to 106-n), such as building management systems and/or IT infrastructure, to relate activities of people or devices to changes in power consumption.

### FIELD OF THE INVENTION

The invention relates to a load monitoring apparatus, method and system for attributing power consumption to different devices in an electrical distribution system.

### BACKGROUND OF THE INVENTION

Energy monitoring solutions are attracting more and more attention due to increasing energy awareness and the wish to better understand the energy consumption to avoid useless waste of energy and money. Smart metering and energy monitoring demand is therefore creating a rapidly growing market in the residential and professional sector. Some products on the market today are able to monitor energy at appliance level to provide consumers with a breakdown of their energy usage. However, in order to do so, they must typically measure consumption at the point of usage, which can become very costly if scaled up to include the entire local electricity network (especially when lighting appliances are included). By contrast, non-intrusive load monitor systems (NILMS), require a single current measurement at a central electricity entrance location, e.g. the meter cupboard, and a single voltage measurement to derive how much energy each device consumes.

In general, many methods exist to monitor the energy consumption of buildings. They either include multiple sensors to collect the energy consumption of multiple devices or try to infer the energy consumption of the individual devices by monitoring the overall energy consumption. The latter approach is extremely interesting due to its low cost (only one sensor for multiple devices) and simple installation. It relies on the fact that different devices have different ways to consume energy. By looking at the time evolution of the overall power, signal processing techniques can be applied to identify the unique transient or steady state behaviour, the current distortions or combinations of characteristics that support the identification of the device. One of the first example of these central load monitoring approach is described in Hart, G. W., “Non-intrusive Appliance Load Monitoring”, Proc. of IEEE, vol.80, No 12, Dec 1992, pp. 1870-1891. More advanced techniques using the current and voltage are described for example in S. B. Leeb et al “Transient event detection in spectral envelope estimates for non-intrusive load monitoring,” IEEE Trans. Power Delivery, vol. 10, no. 3, July 1995, pp. 1200-1210 or in Robert Cox et al, “Transient Event Detection for Nonintrusive Load Monitoring and Demand Side Management Using Voltage Distortion,” IEEE APEC 2006, Page 7. Voltage based techniques use transient sag and swell in voltage (generated due to switching ON/OFF of loads) to establish which type of load got connected/disconnected. They have been also proposed in the scientific literature.

Central monitoring techniques remain however more challenging and suffer from lower reliability since devices with similar energy consumption pattern can be confused. In order for the system to be able to attribute certain power consumption to different appliances the power profile (“signature”) of each appliance has to be known. This requires a database of known signatures and/or training of the system to the learn signatures of unknown devices. This training is cumbersome and may profit from automation.

### SUMMARY OF THE INVENTION

It is an object of the present invention to provide an improved load monitoring system with increased reliability of attribution.

This object is achieved by an apparatus as claimed in claim 1, by a method as claimed in claim 8, and by a computer program product as claimed in claim 9.

Accordingly, other data available in a commercial-building can be used to assist in identifying appliances. Thus, external data is provided as auxiliary information coming e.g. from building management systems (BMS) and/or information technology (IT) infrastructure to relate activities of people or devices to changes in power consumption. E.g., if lights are turned on, this can be detected by a light sensor in a room. The auxiliary data information can thus be used an additional information to enhance or enrich the identification of the device, e.g. with brand, position, etc. With the sensor attached to the BMS, this information can be linked to attribute a rise in power consumption to the lighting in that room. Similarly, activity of networked IT devices is monitored by e.g. an Ethernet switch and can be linked to measured power consumption. As an example, information technology (IT) infrastructure delivers information about activity of certain networked appliances. Hence, auxiliary information about room occupation and lights being on is available. Other types of control systems may be accessed to use their internal information, which in general may have some relation with energy consumption.

According to a first aspect, the at least one external data source may be adapted to provide auxiliary information about at least one of:
activities of switch ports of a local area network powered by the power distribution system,
occupancy of individual rooms powered by the power distribution system,
light level information obtain from a light sensor provided in a building powered by the power distribution system,
indoor temperature obtained from a sensor provided in a building powered by the power distribution system,
outdoor temperature obtained from a sensor provided at a building powered by the power distribution system,
time and date information,
presence or absence information of people working in a building powered by the power distribution system, and
elevator information obtained from an elevator control system of a building powered by the power distribution system. Thus, auxiliary information from a variety of external information sources can be made available to assist identification of power-consuming devices and improve power disaggregation.

According to a second aspect that can be combined with the first aspect, the apparatus may be adapted to learn predetermined patterns of the auxiliary information during a training phase and to use the predetermined pattern for disaggregation of the aggregated power consumption. Thereby, disaggregation speed and performance can be enhanced.

According to a third aspect that can be combined with at least one of the first and second aspects, the detector may be adapted to evaluate the auxiliary information by going back in time from an event detected in the auxiliary information to an event detected in said monitored aggregated power consumption, or vice versa, in order to identify the power consuming device or room. This provides the advantage that time-shifted events can be allocated to each other and disaggregation reliability can be improved.

According to a fourth aspect that can be combined with at least one of the first to third aspects, the detector may be adapted to identify the power consuming device or room based on a combined consideration of auxiliary information from at least two of the external data sources. Hence, vague allocations of detected events can be confirmed by referring the at least one other source or type of auxiliary information.

According to a fifth aspect that can be combined with at least one of the first to fourth aspects, the detector may be adapted to use the auxiliary information for training the central load monitoring system. Thereby, the identification of the power-consuming device can be further specified or concretized.

In a further aspect of the present invention a computer program for performing the above load monitoring method are provided, wherein the computer program comprises code means for causing an apparatus to carry out the steps of the above method when the computer program is run on a computer device controlling the apparatus.

It shall be understood that a preferred embodiment of the invention can also be any combination of the dependent claims with the respective independent claim.

These and other aspects of the invention will be apparent from and elucidated with reference to the embodiments described hereinafter.

### BRIEF DESCRIPTION OF THE DRAWINGS

In the following drawings:

FIG. 1 shows a schematic block diagram of a load monitoring system for determining an operational state of appliances according to an embodiment;

FIG. 2 shows a load monitoring method supported by auxiliary identification according to an embodiment;

FIG. 3 shows an exemplary table of a small part of a log file that shows activity on a switch port of a network;

FIG. 4 shows exemplary time charts of an aggregated lighting power consumption in the morning and in the afternoon, respectively; and

FIG. 5 shows an exemplary time chart of an occupancy information of a specific room.

### DETAILED DESCRIPTION OF EMBODIMENTS

The following embodiments relate to determination of an operational state, for example the power consumption, of electrical appliances, e.g., lamps, a television and a washing machine, or other devices that consume energy. The total energy consumption may be used in a central monitoring system to support the disaggregation of the overall energy. To achieve this, different devices are identified based on device-specific consumption patterns in combination with auxiliary information that can be obtained from at least one of various external data sources providing multi-modal system data.

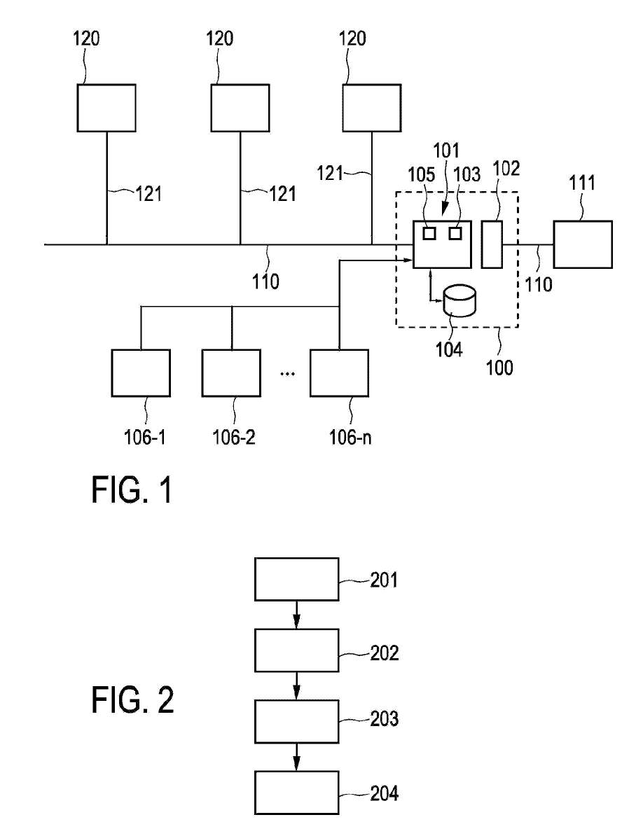

FIG. 1 shows an embodiment of a load monitoring system having a load monitoring device 100 for determining an operational state, e.g. power or energy consumption, of each of a plurality of electrical appliances 120 connected to an electrical installation 110 powered by a power source 111.

The electrical installation 110 is comprised by electrical wiring located between the power source 111 and the load monitoring device 100, and electrical wiring after the load monitoring system 100. The power source 111 may be a utility grid, a local power generator, a solar panel, the battery of an electrical car or other power sources. The appliances 120 are connected to the electrical installation 110 via electrical cables 121 for example using sockets (not shown) of the electrical installation. The load monitoring device 100 comprises a voltage sensor 102 connected to the electrical installation 110 for sensing the voltage on the electrical installation.

The load monitoring device 100 may be connected in series or in parallel with the electrical installation. When the load monitoring device 100 is connected in parallel, the system may simply be connected via a plug to a socket of the electrical installation. When the load monitoring device 100 is connected in series, the system is merely inserted in series with the power source 111 located on one side of the system and the electrical installation 110 located on the other side of the system. Furthermore, the load monitoring device 100 is adapted to apply a disaggregation to obtain the power consumption of individual appliances (e.g., using steady-state current signature based disaggregation). Energy or power disaggregation is understood as the task of taking a whole-home or office energy or power consumption signal and separating it into its component appliances. To achieve this, the load monitoring device 100 is provided with an interface for connecting external data sources 106-1 to 106-n or at least inputting multi-modal system data obtained from the external data sources 106-1 to 106-n as auxiliary information which can be used to assist the disaggregation process. The external data may be any type of other data available in a commercial-building to assist in identifying appliances. IT infrastructure delivers information about activity of certain networked appliances. Furthermore, building management systems contain information about room occupation and lights being on. Other types of control systems may be accessed to use their internal information, which in general may have some relation with energy consumption

Furthermore, the load monitoring device 100 provides an event detection function which monitors the total power consumption, and declares an “ON” or “OFF” event when the power's change or any other observed parameter (transient, real/imaginary delta vector etc.) is within a given range. It may fail in many cases, e.g., appliances with multi-stage power consumption, appliances with long duration of ON/OFF transients. By using the available auxiliary information according to the embodiments, a much more robust event detection and device attribution can be achieved, which is critical for further disaggregation. First, the output event can be used to trigger the disaggregation. The disaggregation usually requires more intensive computation, which should be performed only when necessary. Second, the output event can reduce the search space for disaggregation.

The load monitoring device 100 further comprises a state detector 101 which is connected with the electrical installation 110 for detecting and decoding power profiles of the electrical appliances 120. Optionally, a database 104 for storing power profiles or signatures of electrical appliances 120 can be provided for disaggregation.

The state detector 101 is arranged to measure electrical values on the supply connectors of the electrical installation 110. More specifically, individual device-specific power profiles of the electrical appliances 120 can be obtained by the state detector 101 at the load monitoring device 100 from measurements of electrical values on the electrical supply cables 121, e.g. current or voltage values. Thus, during the operation of the electrical appliances 120, electrical values, for example any changes on the supply cables 121 are monitored or recorded by a pattern detector 105 provided at the state detector 101 in order to detect the appliance-specific power profile.

The state detector 101 further comprises a decoder 103 (e.g. a processor) for comparing a detected power profile with specific known and stored power profiles of the electrical appliances 120. The decoder 103 may be part of the state detector 101 or may be a separate device, e.g. a computer, located elsewhere. If a matching power profile is detected during the comparison, an operational state, e.g. power or energy consumption, may be assigned to the respective electrical appliance. Also, a plurality of possibly different operational states may be assigned to a plurality of different appliances.

The assignment of the operational state may be performed by a processor comprised by the load monitoring device 100, for example the decoder 103 or a different processor. Thus, the actual assignment is performed depending on the result of the comparison of the detected modulation pattern with the appliance power identifiers. The state detector 101, the pattern detector 105 and possibly the decoder 103 may be seen as a load monitoring apparatus which may be fixedly or detachably connected to the electrical installation 110.

The operational state of an appliance may be the current ON or OFF state, the current power or energy consumption, or other operational states or electrical values. Once an operational state has been attributed to an appliance the energy usage per appliance can be determined. The determination of the energy usage may be achieved by the state detector 101, or other processing means. For example, when ON and OFF switching states have been attributed to different appliances together with time information of the power identifiers, then the energy usage can be determined from knowledge of the real power consumption between ON/OFF transitions. These power consumptions may have been determined from measurements of the current or the current harmonics. Alternatively, the power consumption may have been manually entered by a user via the user interface. For example, the power consumption of lamps may be entered manually as an alternative to measuring the consumption.

According to the embodiments, other data available in a commercial-building is used to assist the load monitoring device 100 or decoder 103 in identifying appliances and/or attributing operational states.

FIG. 2 shows a flow diagram of a load monitoring procedure that can be applied in the load monitoring device 100 of the above embodiment.

In step 201, the voltage or current on the electrical installation 110 is monitored, e.g. by the pattern detector 105, and analog-to-digital (A/D) converted for subsequent processing in the digital domain. Then, in step 202, time dependent changes of the monitored output voltage or current are evaluated with regard to their signatures or patterns to identify potential appliances or rooms of the monitored building. In step 203, additional auxiliary information received from at least one of the external data sources 106-1 to 106-n is evaluated to assist identification or disaggregation. Then, in step 204 disaggregation can be applied for the derived appliance or rooms.

In the following, various examples of data sources for the above auxiliary information are presented. The addition of these data can assist in the training phase of a coded power system as well as in the operation phase by limiting the search scope to only those devices that could be active.

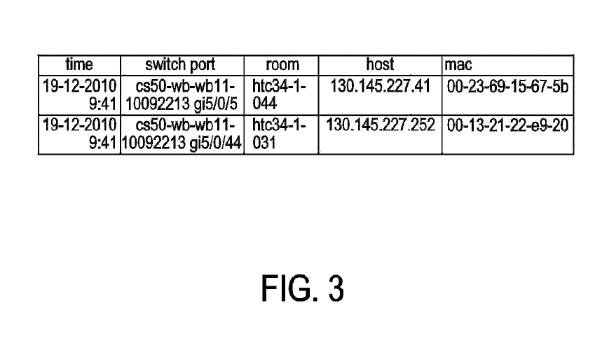

FIG. 3 shows a table which gives an example of a small part of a logfile from a network router or the like, that shows activity on certain Ethernet switch ports and which device that was. By comparing the status on different times, it can be deduced which devices were turned on or off and thus caused changes in the total power consumption. The host Internet Protocol (IP) address and the Media Access Control (MAC) address can be used as auxiliary information about the type of device. For instance, the address “00-13-21-22-e9-20” may be known to be a printer. Apart from the type, also the location is now known. Note that these devices may be active without anybody present.

For lighting however, if modern automated lighting control is installed, the lighting will only be ‘on’ if someone is present (or has been present for the last half hour, say). This information can be stored in a building management Supervisory Control And Data Acquisition (SCADA) system. The primary purpose of SCADA is to control, operate, and monitor multiple sites from a central location. A significant feature of a SCADA system is the trending and forecasting.

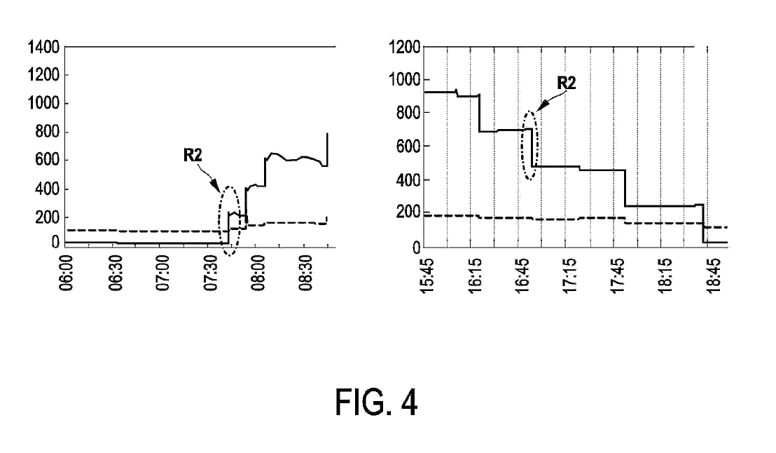

FIG. 4 shows time charts of aggregated lighting power consumption on a specific day, where the left sub-figure corresponds to 6:00 until 8:45 in the morning, and the right sub-figure corresponds to 15:45 until 18:45 in the afternoon. The aggregated lighting power consumption may have been obtained at a single point of measurement e.g. in a meter cupboard, which is contributed by the luminaires in several office rooms and in a corridor. Using a typical disaggregation algorithm, the types of luminaires, the number of luminaires of each type, and the power consumption of each type can be estimated from the aggregated power consumption. The subject of such disaggregation may for example be to calculate a group of reasonable weight coefficients by an optimization method, so that the estimation current has the maximum similarity with the real current.

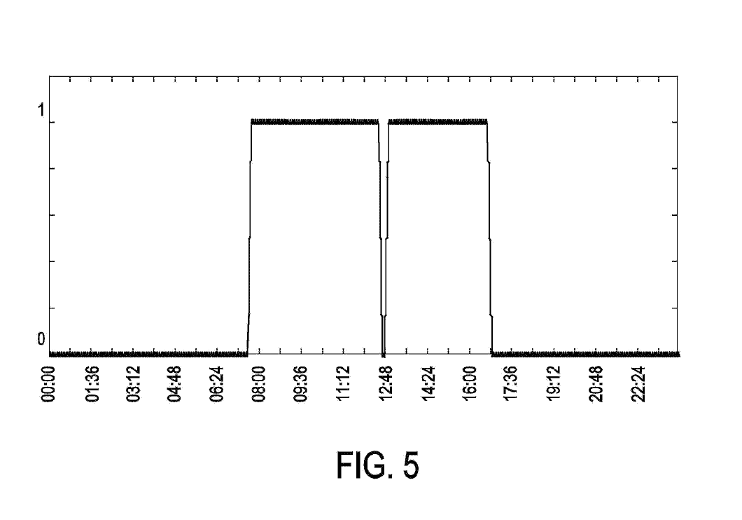

FIG. 5 shows a time chart of occupancy information over 24 hours of a specific day in a specific room (e.g. room R2), where the value “1” means occupancy detected and “0” otherwise. From the occupancy information, it can be derived approximately when the luminaries are “On” and “Off” in this room. Together with the aggregated lighting consumption shown in FIG. 4, it can be identified that the room No. 2 is approximately “On” at 7:40 in the morning, and “Off” at 16:48 in the afternoon.

Using the aggregated power consumption and the room-level occupancy information, not only the disaggregated power consumption at appliance level can be obtained, but also at room-level, which could be more insightful for energy management services.

A third modality may involve light levels as auxiliary information. Some presence detectors may be combined with a local light sensor. This sensor can detect manual switching of lamps (e.g. desk lighting). Since these sensors are connected to the BMS, even information on light sources outside direct reach of the BMS can become available including its location information.

A fourth modality may involve temperature as auxiliary information. By tracking outdoor and indoor temperatures, a relation between electrical energy and temperature can be detected and used. E.g. during cold days, heating devices may be used, or during hot days, the air conditioning will be more active. Depending on the building infrastructure, it may be possible to tap into the thermostats that can even be present in each room. Outdoor temperatures can be obtained from an own sensor or some internet based service. This sensor or service data could also include daylight light level, which again can be used to estimate the switching of the lights inside the building

A fifth modality may involve time and date light levels as auxiliary information. In most cases, there will be a relation between date and time and electrical energy. E.g. in typical offices, switching lights during night time is unlikely. And switching lights on is generally more likely during winter than during summer. All in all, date and time help to make detection and identification of appliances more robust.

A sixth modality may involve electronic presence/absence systems (e.g. employees using badges to check in and out) as sources of auxiliary information. There will likely be a correlation between which or how many people are present and energy consumption patterns. Such patterns can be learned during a training phase and later on used for disaggregation.

Similarly, a seventh modality may involve elevator control systems as sources of auxiliary information.

In general, data from different sensor or modalities are available at times and different rates. For instance, the Ethernet data may only be logged per half hour whereas lighting and presence data are sampled more often. In order to cope with this the load monitoring device 100 can be configured to go back in time from a certain sensor event to an electric event (i.e. change in power consumption). If only one electric event has been detected, it can be concluded—from the sensor data—what caused it. If several electric events are detected, other combinations of sensor data (modalities) need to be considered.

In the embodiments, the auxiliary information may be used to enhance training of the central load monitoring system, e.g. the pattern detector 105 or the decoder 103. This means to support the central load monitoring system in learning which appliance corresponds to the observed electrical events. For instance, the central load monitoring system may observe an ON event of 200 W. The pattern detector 105 detects that there is an appliance 120 (or a state of an appliance) that has an ON event of 200 W. However, the central load monitoring system still does not know which appliance it is. With the auxiliary information the central load monitoring system, e.g. the pattern detector 105 or the decoder 103, can determine which appliance it is. For instance, if this 200 W event happened at the same time that a presence was detected in a room, it is very likely that the light of that room has been switched on. The system can then associate the 200 W (electrical feature) to the lamp (device) and be ‘trained’ by the use of the auxiliary information.

The above embodiments can be applied in any load monitoring system for smart energy monitoring and control applications designed for energy savings and occupant comfort in homes, offices, hotels and buildings, such as for example in products for lighting and lifestyle.

Other variations to the disclosed embodiments can be understood and effected by those skilled in the art in practicing the claimed invention, from a study of the drawings, the disclosure, and the appended claims.

To summarize, the present invention relates to a method and apparatus for disaggregation of energy consumption in a power distribution system. The basic idea is to look at the overall energy consumption and recognize the contributions of each single electrical device, e.g. for the purposes of providing a breakdown of energy consumption to users. Disaggregation is assisted by usage of multi-modal system data coming from various external data sources, such as building management systems and/or IT infrastructure, to relate activities of people or devices to changes in power consumption.

In the claims, the word “comprising” does not exclude other elements or steps, and the indefinite article “a” or “an” does not exclude a plurality.

A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope. The above steps 201 to 204 of FIG. 2 can be performed by a single unit or by any other number of different units. Any calculations, processing and/or control functions of the described load monitoring can be implemented as program code means of a computer program and/or as dedicated hardware.

The computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

1. An apparatus for monitoring load in a power distribution system, said apparatus (100) comprising:
a detector (103, 105) for monitoring an aggregated power consumption of said power distribution system and for identifying a power consuming device (120) or room based on a predetermined power profile or code pattern allocated to said power consuming device; and
an interface for inputting auxiliary information received from at least one external data source (106-1 to 106-n);
wherein said detector (103, 105) is adapted to use said auxiliary data as an additional information for identifying said power consuming device (120).

2. The apparatus according to claim 1, wherein said at least one external data source (106-1 to 106-n) is adapted to provide auxiliary information about at least one of:
activities of switch ports of a local area network powered by said power distribution system,
occupancy of individual rooms powered by said power distribution system,
light level information obtain from a light sensor provided in a building powered by said power distribution system,
indoor temperature obtained from a sensor provided in a building powered by said power distribution system,
outdoor temperature obtained from a sensor provided at a building powered by said power distribution system,
time and date information,
presence or absence information of people working in a building powered by said power distribution system, and
elevator information obtained from an elevator control system of a building powered by said power distribution system.

3. The apparatus according to claim 2, wherein said apparatus is adapted to learn predetermined patterns of said auxiliary information during a training phase and to use said predetermined pattern for disaggregation of said aggregated power consumption.

4. The apparatus according to claim 1, wherein said detector (103, 105) is adapted to evaluate said auxiliary information by going back in time from an event detected in said auxiliary information to an event detected in said monitored aggregated power consumption, or vice versa, in order to identify said power consuming device (120) or room.

5. The apparatus according to claim 1, wherein said detector (103, 105) is adapted to identify said power consuming device (120) or room based on a combined consideration of auxiliary information from at least two of said external data sources (106-1 to 106-n).

6. The apparatus according to claim 1, wherein said data sources (106-1 to 106n) comprise a plurality of sensors arranged in a building powered by said power distribution system.

7. The apparatus according to claim 1, wherein said the detector (103, 105) is adapted to use said auxiliary information for training the central load monitoring system.

8. A method of monitoring load in a power distribution system, said method comprising:
monitoring an aggregated power consumption of said power distribution system;
identifying a power consuming device (120) or room based on a predetermined power profile or a code pattern allocated to said power consuming device;
receiving auxiliary information from at least one external data source (106-1 to 106-n); and
using said auxiliary data as an additional information to enhance the identification of said power consuming device (120)(120).

9. A computer program product comprising code means for producing the steps of method claim 8 when run on a computing device.
